(19) United States
(12) Patent Application Publication
(10) Pub. No.: US 2026/0371936 A1
(43) Pub. Date: Nov. 19, 2026

(54) Spin-Orbit Torque Structure, Magnetic Memory Device Incorporating the Same and Method for Fabricating the Same

(71) Applicant: City University of Hong Kong, Hong Kong (HK)

(72) Inventors: Lifan ZHOU, Hong Kong (HK); Junling WANG, Hong Kong (HK)

(21) Appl. No.: 19/661,680

(22) Filed: Apr. 29, 2026

Related U.S. Application Data
(60) Provisional application No. 63/805,334, filed on May 14, 2025.

(51) Int. Cl. H10N 50/10; G11C 11/16; H01F 10/32; H10N 50/01; H10N 50/85

(52) U.S. Cl. CPC H10N 50/10; H01F 10/3286; H10N 50/01; H10N 50/85; G11C 11/161

(57) ABSTRACT

The present invention provides a spin-orbit torque structure comprising: an oxide layer; a two-dimensional spin-orbit coupling (2D-SOC) layer deposited on the oxide layer; and a free magnetic layer deposited on the 2D-SOC layer. When a switching current is applied to the spin-orbit torque structure: the 2D-SOC layer is configured to provide a primary spin current inducing an out-of-plane anti-damping spin-orbit torque perpendicular magnetic moment; and an auxiliary spin current is generated in an interface between the 2D-SOC layer and the oxide layer. The 2D-SOC layer is thinner than a spin diffusion length of the 2D-SOC layer such that the auxiliary spin current has a stacking enhancing effect on the primary spin current. The structure demonstrates an ultra-low switching current density, representing a significant advancement for low-power spintronic applications.

### CROSS-REFERENCE TO RELATED APPLICATIONS

The present application claims priority from the U.S. Provisional Patent Application No. 63/805,334 filed May 14, 2025, and the disclosure of which is incorporated herein by reference in its entirety.

### FIELD OF THE INVENTION

The present invention relates generally to spintronic devices and magnetic memory technologies, and more particularly to spin-orbit torque structure enabling ultra-low switching current density.

### BACKGROUND OF THE INVENTION

The rapid advancement of artificial intelligence (AI), Internet of Things (IoT), and autonomous systems has led to sky-rocketing demand for high-speed computing and high-density data storage, which is unfortunately accompanied by soaring energy consumption and excessive heat generation. Traditional silicon-based electronics that rely on electron charge for computation and data storage are hitting physical and economic barriers. The decades-long trend of transistor miniaturization predicted by Moore's Law is faltering due to quantum effects and heat dissipation issues, while energy losses from charge leakage and resistive heating further degrade efficiency. These challenges have spurred intensive research on next-generation technologies such as spintronic devices that leverage electron spin rather than charge for low-power data storage and computing, e.g., magnetic random-access memory (MRAM) and spin field-effect transistor (Spin-FET). Regardless of the applications, efficient control of magnetization in ferromagnetic materials with perpendicular magnetic anisotropy (PMA) is of critical importance.

The emerging 3^{rd} generation spin-orbit torque MRAM (SOT-MRAM) represents the significant progress that research on spintronics has achieved in the past decades. In contrast to conventional MRAM, SOT-MRAM devices use the spin current generated by the charge current (rather than the magnetic field generated by the current) and the torque induced by spin accumulation at the interface to switch the relative orientation of the magnetization of the free layers, achieving the data-writing operation.

However, the write (or switching) current density of conventional SOT-MRAM is very high, which limits the density of the memory cell array due to thermal management. Conventional SOT-MRAMs usually use heavy metals (HMs), such as Pt, Ta, etc., or two-dimensional materials, such as Bi₂Te₂Se, WTe₂, etc. as the spin-orbit coupling (SOC) layer, and their switching current density are in the range of 10⁶-10⁷ A/cm⁻². Such a high current density poses significant challenges for the wide spread of SOT-MRAMs.

### SUMMARY OF THE INVENTION

To address the above technical challenges, the present invention provides a spin-orbit torque (SOT) structure enabling ultra-low switching current density by leveraging the synergistic contribution of interface-induced orbital Rashba-Edelstein effects and bulk spin-orbit-coupling-driven spin currents in the 2D-SOC layer, in combination with a symmetry-induced out-of-plane anti-damping torque generated at the SOC/oxide interface.

In accordance with a first aspect of the present invention, provided is a spin-orbit torque structure comprising: an oxide layer; a two-dimensional spin-orbit coupling (2D-SOC) layer deposited on the oxide layer; and a free magnetic layer deposited on the 2D-SOC layer. When a switching current is applied to the spin-orbit torque structure: the 2D-SOC layer is configured to provide a primary spin current inducing an out-of-plane anti-damping spin-orbit torque perpendicular magnetic moment; and an auxiliary spin current is generated in an interface between the 2D-SOC layer and the oxide layer. The 2D-SOC layer is thinner than a spin diffusion length of the 2D-SOC layer such that the auxiliary spin current has a stacking enhancing effect on the primary spin current.

In accordance with a second aspect of the present invention, provided is a memory device comprising: the spin-orbit torque structure of the first aspect; a pinned magnetic layer; a tunnel barrier disposed between the free magnetic layer and the pinned magnetic layer; a bit line electrode electrically connected to the pinned magnetic layer; and a word line electrode electrically connected to the free magnetic layer and the oxide layer. The tunnel barrier exhibits a tunnelling magnetic resistance depending on magnetization states of the free magnetic layer and switchable between a low value and a high value representing a first logic state and a second logic state respectively.

In accordance with a third aspect of the present invention, provided is a method for fabricating the spin-orbit torque structure of the first aspect, comprising: preparing 2D SOC films via dry-transfer or thin film deposition techniques; depositing a metal layer on a substrate through magnetron sputtering and exposing the metal layer to an ambient environment for a predetermined period to allow formation of an oxide layer; sputtering an electrically conductive material on the oxide layer to obtain an electrode layer and performing a lithography process to pattern the electrode layer to obtain patterned electrodes; sequentially picking up, in a controlled atmosphere environment, a free magnetic single crystal film and a 2D SOC film using a selected hexagonal boron nitride (hBN) flake; and sequentially transferring the 2D SOC film and free magnetic single crystal film onto the oxide layer and electrodes on the substrate to form the spin-orbit torque heterostructure.

By optimizing the 2D-SOC layer thickness, the 2D-SOC layer can act as dual-function spin current source with the SOC/oxide interface to enhance spin-charge current interconversion. Deterministic field-free control of magnetization of the free magnetic layer is demonstrated with ultra-low switching current density. A fabricated SOT structure based on FGaT/WTe₂/CuOₓ heterostructure demonstrates an ultra-low switching current density averaging about 3.6×10⁵ Acm⁻² (the smallest current density is 1.4×10⁵ Acm⁻²), one order of magnitude lower than reported values for WTe₂, and about two orders of magnitude lower than that in conventional heavy metal systems. Such ultra-low switching current density represents a significant advancement for low-power spintronic applications, thereby demonstrating the potential of interface-engineered van der Waals heterostructures for beyond-CMOS electronic applications.

### BRIEF DESCRIPTION OF THE DRAWINGS

Embodiments of the invention are described in more details hereinafter with reference to the drawings, in which:

FIG. 1 is a schematic diagram of SOT structure in accordance with one embodiment of the present invention;

FIG. 2 is a schematic diagram of a magnetic memory device comprising the SOT structure in accordance with one embodiment of the present invention;

FIG. 3 is a flowchart of a method for fabricating the SOT structure in accordance with one embodiment of the present invention;

FIGS. 4A and 4B respectively show a 3D isometric view and a cross-sectional view of a SOT structure based on a FGaT/WTe₂/CuOₓ heterostructure in accordance with one embodiment of the present invention, mirror symmetry is preserved about the bc-plane but broken about the ac-plane, where c denotes the out-of-plane axis;

FIG. 5 shows a crystal structure of T_{d}-WTe₂ in the FGaT/WTe₂/CuOₓ heterostructure;

FIG. 6 is an optical micrograph of a hBN/FGaT (~15 nm)/WTe₂(~8 uc)/CuOₓ (~3 nm) heterostructure sample, the current is applied along the a-axis of WTe₂ and transverse voltage along the b-axis is measured;

FIG. 7 shows a current density-Hall resistance curve of an FGT/WTe₂(2 uc)/CuOₓ heterostructure sample without magnetic field;

FIG. 8 is an anomalous Hall effect (AHE) loop measured at room temperature with magnetic field along the out-of-plane direction of a hBN/FGaT (~15 nm)/WTe₂ (~8 uc)/CuOₓ (~3 nm) sample;

FIG. 9 is an anomalous Hall effect (AHE) loop measured at room temperature with current along the a-axis of the hBN/FGaT (~15 nm)/WTe₂ (~8 uc)/CuOₓ (~3 nm) sample;

FIG. 10 illustrates current-induced field-free switching of FGaT magnetization with different WTe₂ thickness;

FIG. 11 illustrates WTe₂ thickness dependence of the critical switching current density (J_{c}), the y-axis coordinate is displayed logarithmically;

FIG. 12 illustrates comparison of J_{c} with reported data of various FGaT/WTe₂/CuOₓ heterostructure devices, the x-axis coordinate is displayed logarithmically.

FIG. 13 illustrates current-induced field-free magnetization switching of FGaT in a hBN/FGaT (~15 nm)/WTe₂ (2 uc)/CuOₓ device at various temperatures;

FIG. 14 illustrates critical current density, J_{c}, of the hBN/FGaT (~15 nm)/WTe₂ (2 uc)/CuOₓ device as a function of temperature;

FIG. 15 illustrates deterministic switching of the hBN/FGaT (~15 nm)/WTe₂ (2uc)/CuOₓ device by a series of current pulses (write pulses: ±300μA, 1 ms; read current: 1μA; pulse interval: 10 s) applied along the a-axis of WTe₂ at temperature 300 K;

FIG. 16 illustrates current-induced R_{xy} curves of hBN/FGaT(~15 nm)/WTe₂(2 uc)/CuOₓ, hBN/FGaT (~15 nm)/WTe₂ (2 uc)/SiO₂, hBN/FGaT (~15 nm)/WTe₂ (2 uc)/Al₂O₃, and hBN/WTe₂ (2 uc)/SiO₂, respectively; and

FIG. 17 illustrates magnetic field-assisted switching of FGaT (~15 nm)/CuOₓ (3 nm), the magnetic field Hₓ is along the current direction.

### DETAILED DESCRIPTION

In the following description, details of the present invention are set forth as preferred embodiments. It will be apparent to those skilled in the art that modifications, including additions and/or substitutions may be made without departing from the scope and spirit of the invention. Specific details may be omitted so as not to obscure the invention; however, the disclosure is written to enable one skilled in the art to practice the teachings herein without undue experimentation.

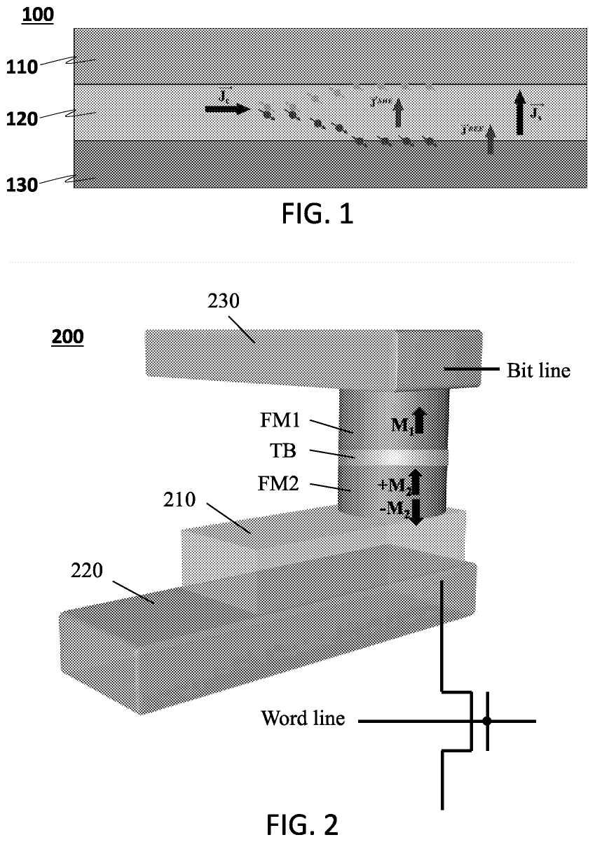

FIG. 1 is a schematic diagram of spin-orbit torque (SOT) structure 100 in accordance with one embodiment of the present invention.

The structure including three layers: a free magnetic layer 110, a two-dimensional (2D) spin-orbit coupling (SOC) layer 120 and an oxide layer 130. The 2D SOC layer 120 provides spin current by spin Hall effect (SHE) to generate an unconventional out-of-plane anti-damping SOT in perpendicular magnetic moment. The free magnetic layer is switched by the SOT generated by the spin current so that field-free current switching is achieved.

When a switching current is applied to the spin-orbit torque structure, the 2D-SOC layer 120 is configured to provide a primary spin current inducing an out-of-plane anti-damping spin-orbit torque perpendicular magnetic moment.

The 2D-SOC layer 120 has a thickness thinner than a spin diffusion length of the SOC material in the SOC layer such that an auxiliary spin current is generated at an interface between the 2D-SOC layer 120 and the oxide layer 130. This auxiliary spin current is generated due to the spin Rashba-Edelstein effect (SREE) or orbital Rashba-Edelstein effect (OREE). As a result, the total spin current can be enhanced by combining the primary spin current of the 2D SOC layer 120 with the auxiliary spin current from the interface. Preferably, the thickness of the 2D-SOC layer 120 is approximately equal to 2 nm.

The free magnetic layer 110 is made of a perpendicular magnetic anisotropy (PMA) material selected from: Fe₃GeTe₂ (FGT), Fe₃GaTe₂ (FGaT), Cr₂Ge₂Te₆ (CGT), Cr₂Si₂Te₆ (CST), Co, CoFeB, CoTb, Tm₃Fe₅O₁₂ (TIG), the like or the combination thereof.

The 2D-SOC layer 120 is made of a thin electrically conductive material with strong SOC elected from: 2D van der Waals materials such as WTe₂, MoTe₂, TaIrTe₄, the like or the combination thereof; heavy metals such as Pt, W, the like or the combination thereof; conductive oxides such as SrIrO₃, SrRuO₃, the like or the combination thereof; topological materials such as Bi₂Se₃, Bi₂Te₃ the like or the combination thereof.

The oxide layer 130 is made of a metal oxide material selected from: CuOₓ, SiO₂, Al₂O₃, SrTiO₃, the like or the combination thereof.

FIG. 2 shows a schematic diagram of a magnetic memory device 200 comprising the SOT structure in accordance with one embodiment of the present invention. As shown, the magnetic memory device 200 comprises a SOT structure including a free magnetic layer (FM2), a 2D-SOC layer 210 and an oxide layer 220. The magnetic memory device further comprises a pinned magnetic layer (FM1) and a tunneling barrier (TB) sandwiched between the free magnetic layer FM2 and the pinned magnetic layer FM1 and configured to provide (or exhibit) a tunnelling magnetic resistance (TMR). The memory device 200 further comprises bit line electrode 230 electrically connected to the pinned magnetic layer; and a word line electrode (not shown) electrically connected to the free magnetic layer and the oxide layer.

When the magnetization of the free magnetic layer FM2 is switched by the SOT generated by the 2D SOC layer 210, the TMR can be read via the bit line electrode (top metal) 230 and a low current density SOT magnetization switching current flowing through the word line electrode can achieve high-speed and low-power writing in the memory device.

The tunnel barrier may be made of an inorganic ceramic material selected from: MgO, TiO₂, Al₂O₃, MgZnO, MgB₂, Ti₃N₄, V₃N₄, BN, the like or the combination thereof. In some embodiments, the tunnel barrier may have a multiple layer structure (like Mg/MgO alternately stacked).

The pinned magnetic layer may be made of a traditional ferromagnetic material selected from Fe, Co, Ni, CoFe, NiFe, CoFeB, NiFeB, CoFeSiB, NiFeSiB, (Pt/Co)ₙ, the like or the combination thereof arranged in alloy/multilayer structures. The pinned magnetic layer may have a fixed magnetization direction, which can be parallel or antiparallel to the magnetization direction of the free magnetic layer FM2.

The value of the TMR depends on the relative orientation of the magnetization directions of the two magnetic layers FM1 and FM2. When the magnetization direction of the fixed layer and the free layer is parallel, the majority spin electrons (electrons with the same magnetization direction) are in low energy states on both sides, and the tunneling probability is high. Then the TMR has a low value (corresponding to logic “0”). When the magnetization directions of the two magnetic layers are antiparallel, the TMR has a high value (corresponding to logic “1”).

The fabrication of the SOT structure involves meticulous stacking of a free magnetic single crystal film and a 2D SOC single crystal film onto an oxide layer with patterned electrical contacts. The stacking may be performed through dry-transfer techniques or thin film deposition technology.

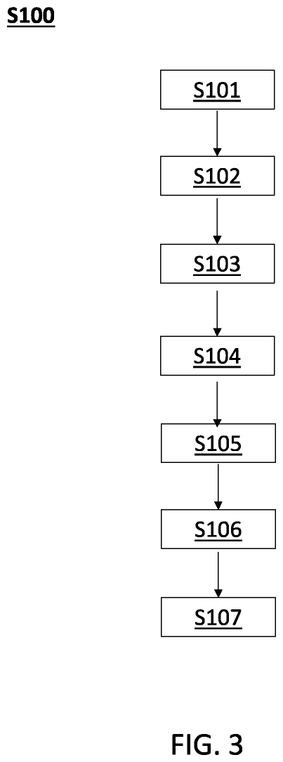

Referring to FIG. 3, the device fabrication process S100 comprises the steps of:
S101: preparing 2D SOC single crystal films via dry-transfer or thin film deposition techniques.
S102: depositing a metal layer on an insulating layer coated on a substrate through magnetron sputtering and exposing the metal layer to an ambient environment for a predetermined period to form an oxide layer.
S103: sputtering an electrically conductive material on the oxide layer to obtain an electrode layer and performing a lithography process to pattern the electrode layer to obtain patterned electrodes.
S104: mechanically exfoliating hBN into flakes, and selecting hBN flakes having a thickness in a range of about 20 nm to 50 nm.
S105: lifting the selected hBN flakes using a polymer-based transfer stamp.
S106: sequentially picking up, in a controlled atmosphere environment, a free magnetic single crystal film and a 2D SOC film using the selected hBN flake carried by the transfer stamp.
S107: sequentially transferring the 2D SOC film and free magnetic single crystal film onto the oxide layer and electrodes to form the SOT heterostructures.

In one embodiment, a Fe₃GaTe₂ (FGaT)/WTe₂/CuOₓ heterostructure device is fabricated as a SOT structure. The fabrication involves meticulous assembly of FGaT and WTe₂ layers of various thickness onto a CuOₓ/SiO₂/Si substrate with patterned Pt electrical contacts using dry-transfer techniques.

More specifically, single crystal film of WTe₂ was synthesized via chemical vapor transport (CVT), stoichiometric mixtures of W and Te powders with a transport agent were sealed in an evacuated quartz tube and placed in a two-zone furnace. The source and growth zones were maintained at 750 °C and 650 °C respectively for 10 days, yielding mm-sized crystals in the growth zone.

The CuOₓ layer was prepared by magnetron sputtering of 3 nm Cu on SiO₂ (300 nm) coated on Si substrate. The sputtered Cu is then left to oxidize in air under ambient conditions for two days to achieve the CuOₓ layer through natural oxidation of Cu.

Then ultraviolet lithography and magnetron sputtering techniques were used to make Hall-shaped (~8 um×3 um) Pt (10 nm) electrodes on the SiO₂ (300 nm) coating. hBN was then exfoliated onto the SiO₂ substrate using Scotch tape, and appropriate sizes and thicknesses of hBN were selected under a microscope. Subsequently, hBN successively lifted using a PC/PDMS stamp. Then, FGaT and WTe₂ with appropriate shape and thickness was lifted using the hBN inside a glovebox (with an oxygen content below 0.5 ppm) and transferred onto the Hall-shaped electrodes. Preferably, WTe₂ single crystal films of rectangular shape are selected, where the long and short edges correspond to the a- and b-axis, respectively. FGaT films having sizes smaller than the WTe₂ single crystal films are then selected.

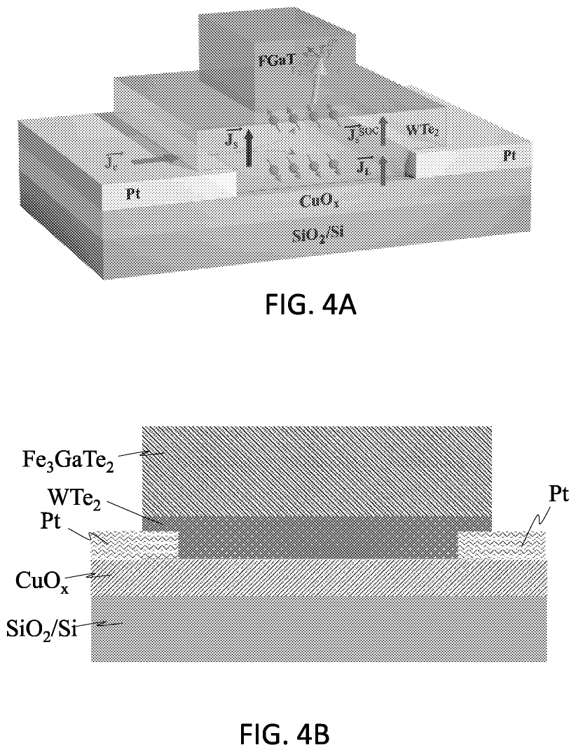

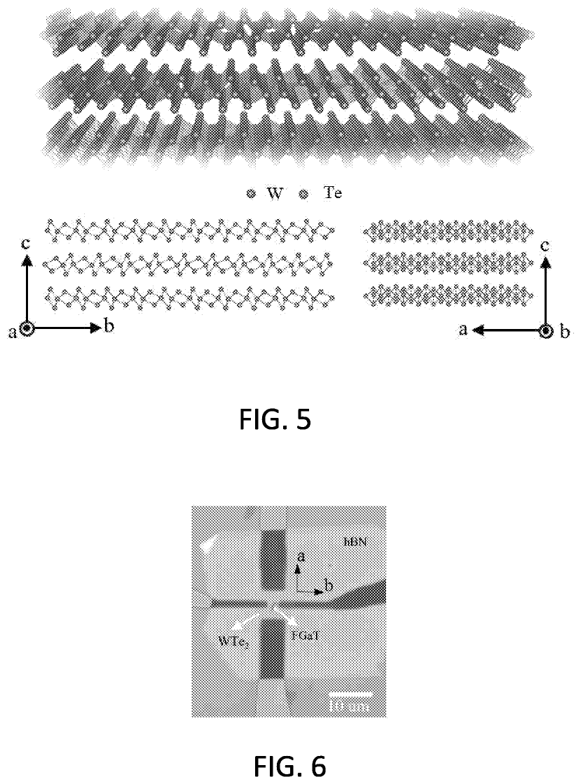

FIGS. 4A and 4B schematically illustrate the structure of the FGaT/WTe₂/CuOₓ heterostructure device. The FGaT/WTe₂/CuOₓ heterostructure device has a WTe₂ 2D-SOC layer with a thickness thinner than 4 unit cells (uc). The T_{d}-phase WTe₂ employed in the present invention (space group Pnm2₁) exhibits distinct symmetry characteristics: while mirror symmetry is preserved about the bc-plane, it is broken about the ac-plane, where c denotes the out-of-plane crystallographic axis (FIG. 5).

The measurement of Hall resistance involves applying a current along the a-axis of WTe₂ while detecting the transverse voltage along the b-axis (FIG. 6), enabling precise detection of magnetization switching in FGaT.

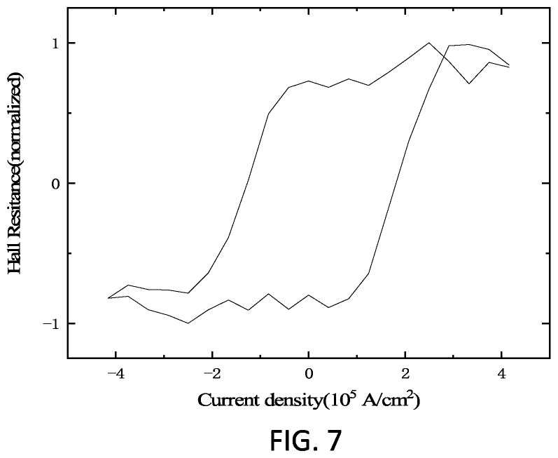

FIG. 7 shows a current density-Hall resistance curve of a FGT/WTe₂ (2 uc)/CuOₓ sample without magnetic field. There exhibits a low switching current density (~1.56×10⁵ A cm⁻²), which is reduced by 1-2 order of magnitude as compared to literature values.

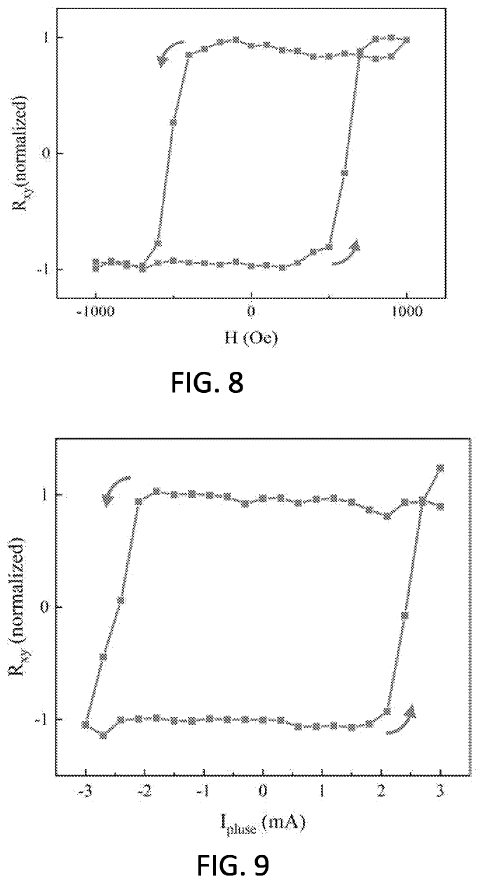

FIG. 8 displays the anomalous Hall effect (AHE) hysteresis loop of another device (hBN/FGaT(~15 nm)/WTe₂ (~8 uc)/CuOₓ (~3 nm)) measured at room temperature with the magnetic field applied normal to the plane (H∥c).

Field-free electric current switching of the magnetization was also achieved using 1 ms current pulses at room temperature (FIG. 9). Subsequent measurements, unless otherwise specified, were all conducted at room temperature (300 K).

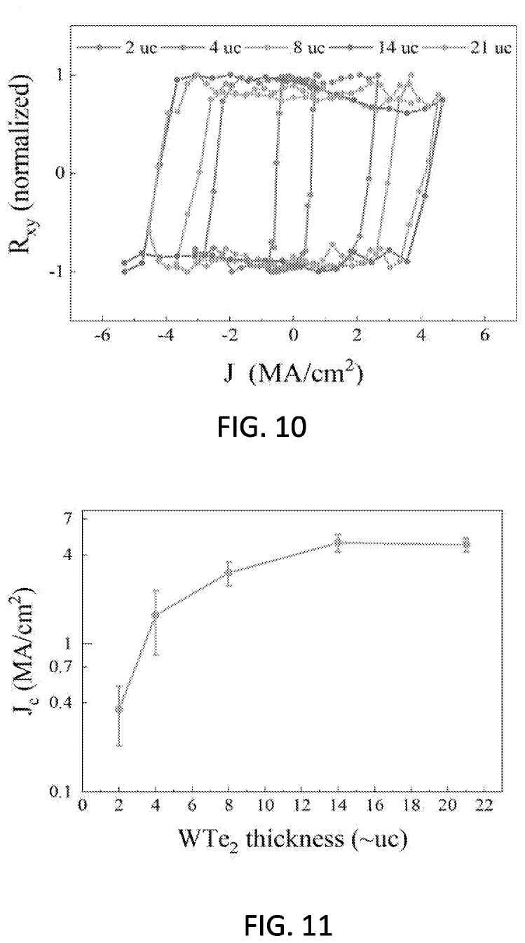

In FIG. 10, the current-induced field-free magnetization switching characteristics of the devices with varying WTe₂ thicknesses are plotted as functions of current density.

From these measurements, the critical switching current density (J_{c}) are extracted. If uneven current splitting effect between the FGaT and WTe₂ layers is considered, the J_{c} would be even smaller for devices with thin WTe₂.

As illustrated in FIG. 11, a substantial reduction in J_{c} is observed with decreasing WTe₂ thickness. Notably, the average J_{c} for 2 uc WTe₂ device is 3.6×10⁵ A cm⁻² (the smallest J_{c} is about 1.4×10⁵ A cm⁻²).

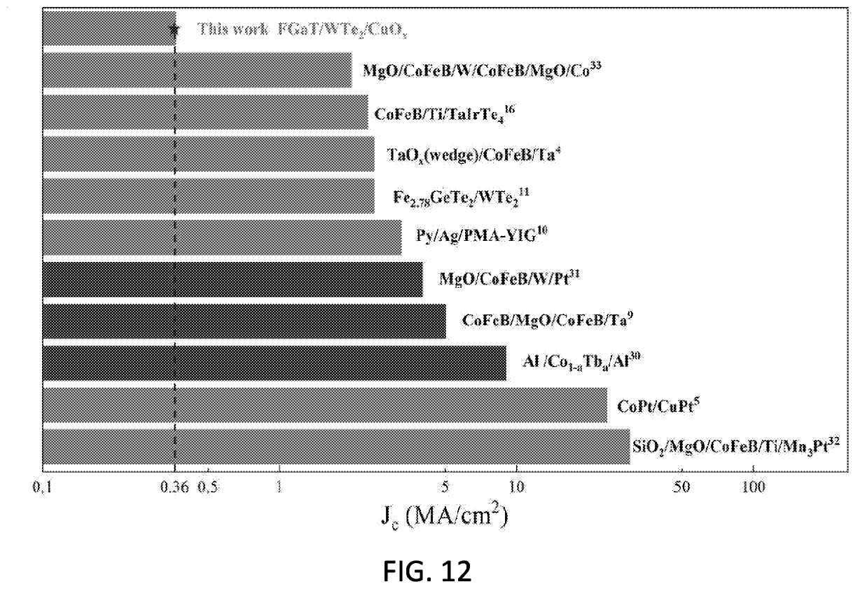

This field-free magnetization switching J_{c} is one to two orders of magnitude smaller than previously reported values, as shown in FIG. 12, highlighting its extraordinary potential for energy-efficient spintronic applications. In contrast, as the WTe₂ thickness increases, J_{c} gradually saturates at ~4.7×10⁶ A cm⁻² for the 21 uc WTe₂ device, close to the previously reported values.

The reduction in critical switching current density achieved by the present invention is based on two mechanisms: the (spin) Rashba-Edelstein effect (SREE) and the orbital Rashba-Edelstein effect (OREE). In both cases, additional spin current is induced in WTe₂, leading to enhanced spin accumulation and increased SOT at the FGaT/WTe₂ interface.

On the other hand, charge current can induce an orbital angular momentum flow (orbital current J_{L}) at metal/oxide interfaces, which can then be converted to a spin current (Jₛ^{SOC}) in the metal with SOC. If this additional spin current adds onto the intrinsic spin current (Jₛ) of WTe₂ in the WTe₂/CuOₓ heterostructures, much enhanced spin accumulation and SOT at the FGaT/WTe₂ interface would occur when WTe₂ is thin.

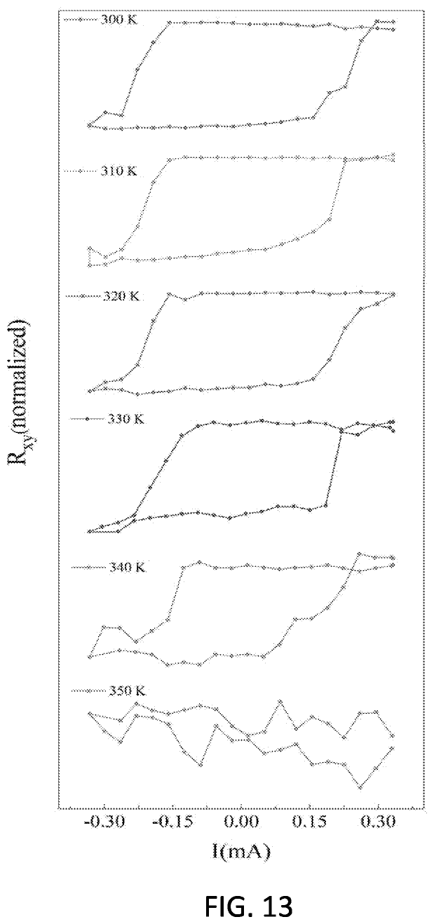

To further confirm the observations, more comprehensive magneto-transport characterizations were conducted on hBN/FGaT(~15 nm)/WTe₂ (2 uc)/CuOₓ (~3 nm) device. FIG. 13 shows the current-induced field-free magnetization switching of FGaT over a temperature range of 300 K-350 K. Up to 340 K, deterministic magnetization reversal can be observed, while no discernible switching loop observed at 350 K.

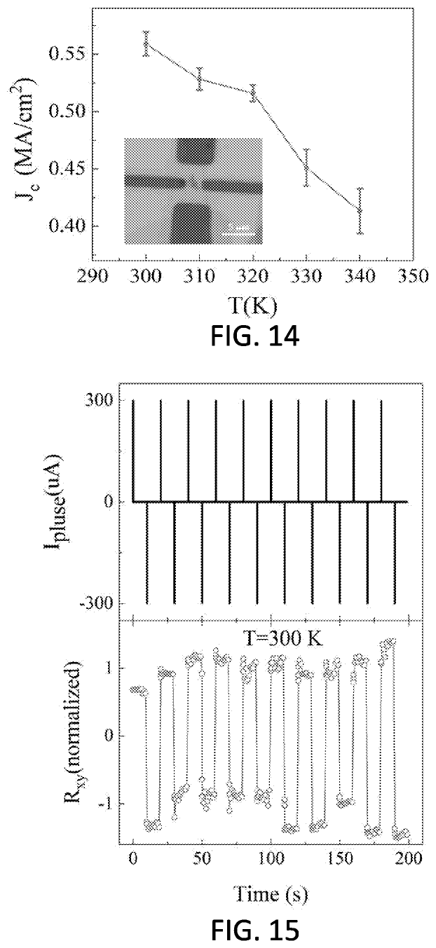

As shown in FIG. 14, J_{c} decreases with rising temperature. This trend aligns with the thermal evolution of both magnetization and coercive field of FGaT, which progressively weaken upon approaching its Curie temperature. The synthesized bulk FGaT single crystal's Curie temperature is about 370 K, while the T_{c} of thin layer FGaT may decrease. Finally, robust magnetization control through current pulses of opposite direction applied along the a-axis of WTe₂ at 300 K are demonstrated, as illustrated in FIG. 15.

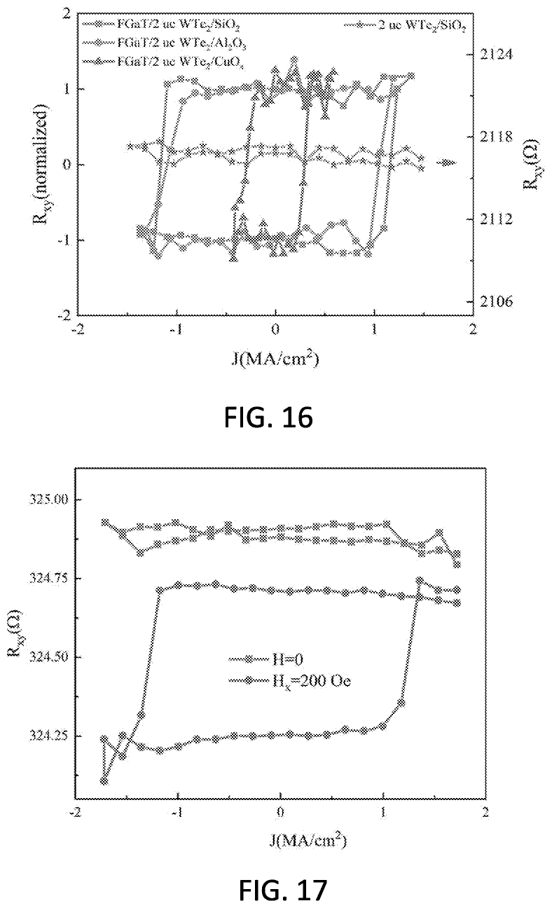

To elucidate the role of the WTe₂/CuOₓ interface in the SOT-induced magnetization switching in the fabricated hBN/FGaT/WTe₂/CuOₓ, comparative studies are performed on three more device configurations: hBN/FGaT/WTe₂/SiO₂, hBN/FGaT/WTe₂/Al₂O₃, and hBN/WTe₂/SiO₂. All of the four device configurations have the same FGaT layer thickness (~15 nm) and WTe₂ layer thickness (2 uc). FIG. 16 presents the current-induced R_{xy} curves measured at room temperature under zero magnetic field.

Pronounced magnetization switching loops were observed in Devices hBN/FGaT/WTe₂/CuOₓ, hBN/FGaT/WTe₂/CuOₓ and hBN/FGaT/WTe₂/Al₂O₃, which incorporate FGaT, with J_{c} of ~2.8×10⁵, 1.2×10⁶, 1.1×10⁶ Acm⁻², respectively. These reduced J_{c} (especially for FGaT/WTe₂/CuOₓ devices) compared to thicker WTe₂-based devices suggests enhanced charge to spin conversion efficiency from WTe₂ bottom interface and stronger SOT on FGaT.

Furthermore, control experiments on hBN/FGaT CuOₓ (3 nm) heterostructures revealed that while magnetic field-assisted switching could be achieved (J_{c}~1.2×10⁶ A cm⁻² with 200 Oe magnetic field along the current direction), as shown in FIG. 17, field-free switching was not observed in the device.

While the present disclosure has been described and illustrated with reference to specific embodiments thereof, these descriptions and illustrations are not limiting. The illustrations may not necessarily be drawn to scale. There may be distinctions between the illustrations in the present disclosure and the actual apparatus due to manufacturing processes and tolerances. There may be other embodiments of the present disclosure which are not specifically illustrated. Modifications may be made to adapt a particular situation, material, composition of matter, method, or process to the objective and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations.

What is claimed is:

1. A spin-orbit torque structure comprising:
an oxide layer;
a two-dimensional spin-orbit coupling (2D-SOC) layer deposited on the oxide layer; and
a free magnetic layer deposited on the 2D-SOC layer;
wherein when a switching current is applied to the spin-orbit torque structure: the 2D-SOC layer is configured to provide a primary spin current inducing an out-of-plane anti-damping spin-orbit torque perpendicular magnetic moment; and an auxiliary spin current is generated in an interface between the 2D-SOC layer and the oxide layer; and
the 2D-SOC layer is thinner than a spin diffusion length of the 2D-SOC layer such that the auxiliary spin current has a stacking enhancing effect on the primary spin current.

2. The spin-orbit torque structure according to claim 1, wherein the free magnetic layer is made of a perpendicular magnetic anisotropy material.

3. The spin-orbit torque structure according to claim 1, wherein the 2D-SOC layer is made of an electrically conductive material with spin-orbit coupling.

4. The spin-orbit torque structure according to claim 1, wherein the oxide layer is made of a metal oxide material.

5. A memory device comprising:
the spin-orbit torque structure according to claim 1;
a pinned magnetic layer;
a tunnel barrier disposed between the free magnetic layer and the pinned magnetic layer;
a bit line electrode electrically connected to the pinned magnetic layer; and
a word line electrode electrically connected to the free magnetic layer and the oxide layer;
wherein the tunnel barrier exhibits a tunnelling magnetic resistance depending on magnetization states of the free magnetic layer and switchable between a low value and a high value representing a first logic state and a second logic state respectively.

6. The memory device according to claim 5, wherein the free magnetic layer is made of a perpendicular magnetic anisotropy material.

7. The memory device according to claim 5, wherein the 2D-SOC layer is made of an electrically conductive material with spin-orbit coupling.

8. The memory device according to claim 5, wherein the oxide layer is made of a metal oxide material.

9. The memory device according to claim 5, wherein the pinned magnetic layer is made of a ferromagnetic material.

10. The memory device according to claim 5, wherein the tunnelling barrier is made of an inorganic ceramic material.

11. A method for fabricating the spin-orbit torque structure according to claim 1, comprising:
preparing 2D SOC films via dry-transfer or thin film deposition techniques;
depositing a metal layer on a substrate through magnetron sputtering and exposing the metal layer to an ambient environment for a predetermined period to allow formation of an oxide layer;
sputtering an electrically conductive material on the oxide layer to obtain an electrode layer and performing a lithography process to pattern the electrode layer to obtain patterned electrodes;
sequentially picking up, in a controlled atmosphere environment, a free magnetic single crystal film and a 2D SOC film using a selected hBN flake; and
sequentially transferring the 2D SOC film and free magnetic single crystal film onto the oxide layer and electrodes on the substrate to form the spin-orbit torque heterostructure.
